(19) United States
(12) Patent Application Publication
(10) Pub. No.: US 2023/0074772 A1
(43) Pub. Date: Mar. 9, 2023

(54) DISPLAY PANEL

(71) Applicant: Samsung Display Co., Ltd., Yongin-si (KR)

(72) Inventors: SEON YOUNG CHOI, Gunpo-si (KR); JUNKI JEONG, Yongin-si (KR); JAEHYUNG CHO, Suwon-si (KR); MINDO HEO, Gunpo-si (KR)

(21) Appl. No.: 17/871,226

(22) Filed: Jul. 22, 2022

(30) Foreign Application Priority Data
Sep. 7, 2021 (KR) 10-2021-0119314

(51) Int. Cl. H01L 27/32; G09G 3/3233

(52) U.S. Cl. CPC H01L 27/3276; G09G 3/3233; H01L 27/3211; G09G 2300/0842; G09G 2300/0819; G09G 2300/0861; G09G 2300/0452; G09G 2310/08

(57) ABSTRACT

A display panel includes a base layer including a boundary area and a pixel area, a pixel circuit that overlaps the pixel area, a plurality of insulating layers which includes at least a first insulating layer and in which an opening overlapping the boundary area is defined, a first signal line that is disposed on the first insulating layer and that overlaps the boundary area and the pixel area, an organic layer including a first portion that fills the opening, and a light-emitting element disposed over the plurality of insulating layers and electrically connected to the pixel circuit. The opening includes a first area that overlaps the first signal line and has a first depth and a second area having a second depth greater than the first depth.

This application claims priority to Korean Patent Application No. 10-2021-0119314, filed on Sep. 7, 2021, and all the benefits accruing therefrom under 35 U.S.C. § 119, the content of which in its entirety is herein incorporated by reference.

### BACKGROUND

### 1. Field

Embodiments of the invention described herein relate to a flexible display panel.

### 2. Description of the Related Art

A display device includes a display panel, and the display panel includes light-emitting elements and transistors for controlling electrical signals applied to the light-emitting elements. To accurately control a degree to which the light-emitting elements emit light, the number of transistors electrically connected to one light-emitting element is increased, and the number of wires that transfer electrical signals to the transistors is also increased. Accordingly, a method for improving design integration and manufacturing efficiency of the display panel is desired.

### SUMMARY

Embodiments of the invention provide a display panel having improved manufacturing efficiency and an improved degree of integration.

In an embodiment, a display panel includes a base layer including a boundary area and a pixel area, a pixel circuit that overlaps the pixel area, a plurality of insulating layers which includes at least a first insulating layer and in which an opening overlapping the boundary area is defined, a first signal line that is disposed on the first insulating layer and that overlaps the boundary area and the pixel area, an organic layer including a first portion that fills the opening, and a light-emitting element disposed on the plurality of insulating layers and electrically connected to the pixel circuit. The opening includes a first area that overlaps the first signal line and has a first depth and a second area having a second depth greater than the first depth.

In an embodiment, the plurality of insulating layers may further include a second insulating layer disposed on the first insulating layer. The display panel may further include a second signal line that is disposed on the second insulating layer and that overlaps the boundary area and the pixel area. The opening may further include a third area that overlaps the second signal line and has a third depth smaller than the first depth.

In an embodiment, the second area may not overlap the first signal line and the second signal line.

In an embodiment, the first signal line and the second signal line may extend in a first direction, and the first area and the third area may be spaced apart from each other with the second area therebetween in a second direction crossing the first direction.

In an embodiment, in the pixel area, the second insulating layer may cover the first signal line.

In an embodiment, in the boundary area, a first surface of the organic layer facing the base layer contacts may contact the first signal line and the second signal line.

In an embodiment, the display panel may further include a barrier layer disposed on the base layer, and the opening may expose the barrier layer in the second area.

In an embodiment, in the second area, the barrier layer may contact the organic layer.

In an embodiment, the pixel circuit may include a first transistor including a first source area, a first drain area, a first channel area, and a first gate and a second transistor including a second source area, a second drain area, a second channel area disposed in a different layer from the first channel area, and a second gate disposed in a different layer from the first gate. The first signal line may be disposed in the same layer as the first gate or the second gate.

In an embodiment, the second transistor may further include a third gate electrically connected with the second gate and disposed in a different layer from the first gate and the second gate.

In an embodiment, the first transistor may be a silicon transistor, and the second transistor may be an oxide transistor.

In an embodiment, the boundary area may include a first boundary area that extends in a first direction and a second boundary area that extends in a second direction crossing the first direction, and the first signal line may extend in the first direction.

In an embodiment, the plurality of insulating layers may further include a buffer layer disposed under the first insulating layer, a second insulating layer disposed on the first insulating layer, and a third insulating layer disposed on the second insulating layer. The first area may penetrate the second insulating layer and the third insulating layer, and the second area may penetrate the buffer layer and the first to third insulating layers.

In an embodiment, the first insulating layer may include a first insulating portion that overlaps the boundary area. A first opening and a second opening may be defined in the first insulating layer with the first insulating portion therebetween. The first opening and the second opening may constitute a portion of the opening of the plurality of insulating layers.

In an embodiment, the plurality of insulating layers may further include a second insulating layer disposed on the first insulating layer. The second insulating layer may include a second insulating portion that overlaps the boundary area. A third opening and a fourth opening may be defined in the second insulating layer with the second insulating portion therebetween. The third opening and the fourth opening may constitute a portion of the opening of the plurality of insulating layers.

In an embodiment, the display panel may further include an organic insulating layer that is disposed on the first portion and an outermost insulating layer farthest from the base layer among the plurality of insulating layers and that contacts the first portion and the outermost insulating layer and a data line disposed on the organic insulating layer.

In an embodiment, the data line may be connected to the pixel circuit through a contact hole defined through the organic layer.

In an embodiment, the organic layer may further include a second portion that extends from the first portion and overlaps the boundary area and the pixel area.

In an embodiment, the display panel may further include a data line disposed on the second portion, and the data line may be connected to the pixel circuit through a contact hole defined through the second portion.

In an embodiment, the pixel area may include a plurality of pixel areas. The boundary area may surround each of the plurality of pixel areas in a plan view. One light-emitting element, two light-emitting elements, or four light-emitting elements may be disposed in each of the pixel areas.

### BRIEF DESCRIPTION OF THE DRAWINGS

The above and other objects and features of the invention will become apparent by describing in detail embodiments thereof with reference to the accompanying drawings.

FIG. 1 is a plan view of an embodiment of a display panel.

FIG. 2 is a cross-sectional view of an embodiment of the display panel.

FIG. 3A is a block diagram of an embodiment of a display device.

FIG. 3B is an equivalent circuit diagram of an embodiment of a pixel.

FIG. 3C illustrates waveform diagrams of an embodiment of drive signals for driving the pixel.

FIG. 4 is an enlarged plan view of an embodiment of the display panel.

FIG. 5A is a cross-sectional view of an embodiment of the display panel.

FIG. 5B is a cross-sectional view of an embodiment of the display panel.

FIG. 6 is a plan view of an embodiment of a pixel area.

FIGS. 7A to 7H are plan views illustrating an embodiment of components in the pixel area in a stacking order.

FIG. 8A is a cross-sectional view illustrating a portion corresponding to line I-I′ of FIG. 6.

FIG. 8B is a cross-sectional view illustrating a portion corresponding to line II-IF of FIG. 6.

FIG. 8C is a cross-sectional view illustrating an embodiment of a portion of the display panel.

FIG. 9A is an enlarged plan view of an embodiment of the display panel.

FIG. 9B is an enlarged plan view of an embodiment of the display panel.

### DETAILED DESCRIPTION

Various changes may be made to the invention, and various embodiments of the invention may be implemented. Thus, embodiments are illustrated in the drawings and described as examples herein. However, it should be understood that the invention is not to be construed as being limited thereto and covers all modifications, equivalents, and alternatives falling within the spirit and scope of the invention.

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the invention, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the invention pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Hereinafter, a display panel in an embodiment will be described with reference to the accompanying drawings.

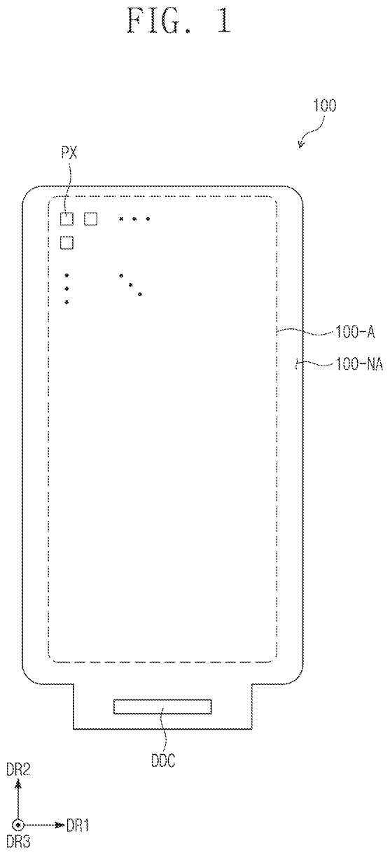

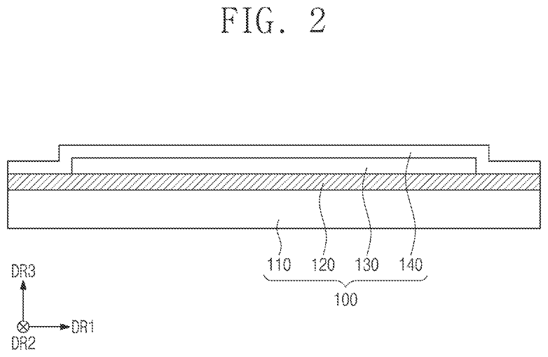

FIG. 1 is a plan view of an embodiment of a display panel 100. FIG. 2 is a cross-sectional view of an embodiment of the display panel 100.

Referring to FIG. 1, the display panel 100 may include a display area 100-A and a non-display area 100-NA. The non-display area 100-NA may be adjacent to the display area 100-A and may surround at least part of the display area 100-A. Pixels PX may be disposed in the display area 100-A and may not be disposed in the non-display area 100-NA. A data drive circuit DDC may be disposed on one side of the non-display area 100-NA.

The display area 100-A may include a plane defined by a first direction DR1 and a second direction DR2. A thickness direction of the display panel 100 may be parallel to a third direction DR3 that is the normal direction of the display area 100-A. Front surfaces (or, upper surfaces) and rear surfaces (or, lower surfaces) of members constituting the display panel 100 may be defined with respect to the third direction DR3.

The display panel 100 may be an emissive display panel. In an embodiment, the display panel 100 may be an organic light-emitting display panel, an inorganic light-emitting display panel, a micro light-emitting diode (“LED”) display panel, or a nano LED display panel, for example. The display panel 100 may be a flexible display panel. Although not illustrated, the display panel 100 may be folded about at least one folding axis. A folding area may cross the display area 100-A.

Referring to FIG. 2, the display panel 100 may include a base layer 110, a circuit layer 120, a light-emitting element layer 130, and an encapsulation layer 140. Unlike that illustrated in FIG. 2, a functional layer may be additionally disposed between two layers adjacent to each other among the base layer 110, the circuit layer 120, the light-emitting element layer 130, and the encapsulation layer 140.

The base layer 110 may provide a base surface on which the circuit layer 120 is disposed. The base layer 110 may be a flexible substrate that may be bent, folded, or rolled. The base layer 110 may be a glass substrate, a metal substrate, a polymer substrate, or the like. However, without being limited thereto, the base layer 110 may include an inorganic layer, an organic layer, or a composite layer.

The base layer 110 may include multiple layers. In an embodiment, the base layer 110 may include a first synthetic resin layer, an inorganic layer having a multi-layer structure or a single-layer structure, and a second synthetic resin layer disposed on the inorganic layer having the multi-layer structure or the single-layer structure, for example. Each of the first synthetic resin layer and the second synthetic resin layer may include a polyimide-based resin, but is not particularly limited.

The circuit layer 120 may be disposed on the base layer 110. The circuit layer 120 may include an insulating layer, a semiconductor pattern, a conductive pattern, a signal line, or the like.

The light-emitting element layer 130 may be disposed on the circuit layer 120. The light-emitting element layer 130 may include light-emitting elements. In an embodiment, the light-emitting elements may include an organic light-emitting material, an inorganic light-emitting material, an organic-inorganic light-emitting material, a quantum dot, a quantum rod, a micro LED, or a nano LED, for example.

The encapsulation layer 140 may be disposed on the light-emitting element layer 130. In an embodiment, the encapsulation layer 140 may protect the light-emitting element layer 130 from foreign matter such as moisture, oxygen, or dust particles. The encapsulation layer 140 may include at least one inorganic layer. The encapsulation layer 140 may include a structure in which an inorganic layer, an organic layer, and an inorganic layer are sequentially stacked.

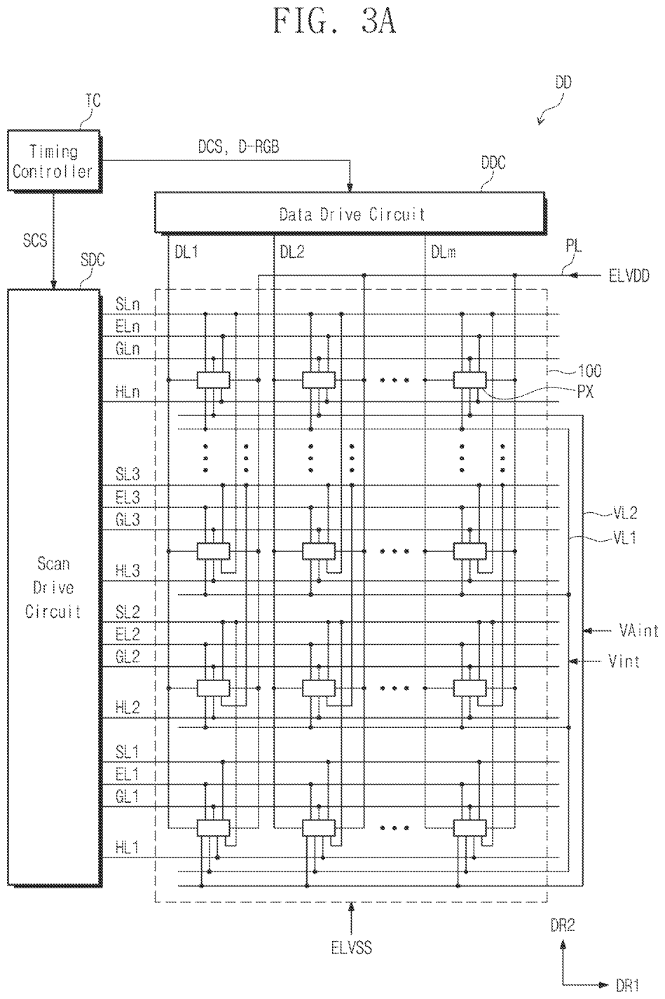

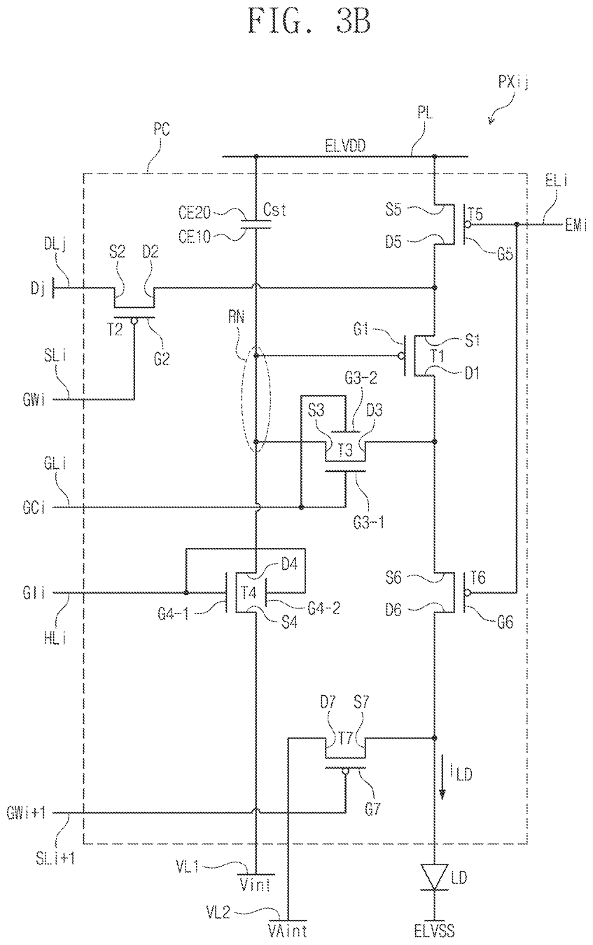

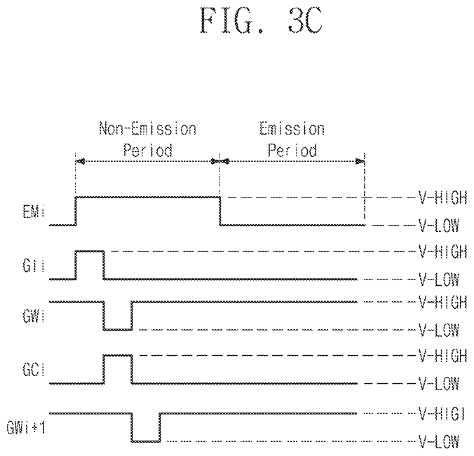

FIG. 3A is a block diagram of an embodiment of a display device DD. FIG. 3B is an equivalent circuit diagram of an embodiment of a pixel PX. FIG. 3C illustrates waveform diagrams of an embodiment of drive signals for driving the pixel PX in an embodiment

The display device DD may include a timing controller TC, a scan drive circuit SDC, the data drive circuit DDC, and the display panel 100. At least one of the timing controller TC, the scan drive circuit SDC, or the data drive circuit DDC may be provided in the form of a driver integrated circuit (“IC”), or may be directly formed or disposed on the display panel 100.

The timing controller TC may receive input image signals and may generate image data D-RGB by converting the data format of the input image signals according to the specification of an interface with the scan drive circuit SDC. The timing controller TC may output the image data D-RGB and various control signals DCS and SCS.

The scan drive circuit SDC may receive the scan control signal SCS from the timing controller TC. The scan control signal SCS may include a vertical start signal to start operation of the scan drive circuit SDC and a clock signal to determine the time to output signals. The scan drive circuit SDC may generate a plurality of scan signals and may sequentially output the scan signals to corresponding signal lines SL1 to SLn, GL1 to GLn, and HL1 to HLn. Here, n may be a natural number. Furthermore, the scan drive circuit SDC may generate a plurality of emission control signals in response to the scan control signal SCS and may output the emission control signals to corresponding emission lines EL1 to ELn.

In FIG. 3A, the plurality of scan signals and the plurality of emission control signals are illustrated as being output from the one scan drive circuit SDC. However, the invention is not limited thereto. In an embodiment, a plurality of scan drive circuits may be provided, for example. The plurality of scan drive circuits may separately generate and output scan signals and may separately generate and output a plurality of emission control signals. Furthermore, a drive circuit for generating and outputting a plurality of scan signals and a drive circuit for generating and outputting a plurality of emission control signals may be separately distinguished from each other.

The data drive circuit DDC may receive the data control signal DCS and the image data D-RGB from the timing controller TC. The data drive circuit DDC may convert the image data D-RGB into data signals and may output the data signals to a plurality of data lines DL1 to DLm to be described below. Here, m may be a natural number. The data signals may be analog voltages corresponding to gray level values of the image data D-RGB.

The display panel 100 may include a plurality of groups of signal lines. When one of the plurality of groups of signal lines is defined as a first signal line, another one may be defined as a second signal line, and another one may be defined as a third signal line. Hereinafter, to distinguish the plurality of groups of signal lines, the names of the signal lines are defined.

The plurality of groups of signal lines may include the first group of scan lines SL1 to SLn, the second group of scan lines GL1 to GLn, the third group of scan lines HL1 to HLn, the emission lines EL1 to ELn, the data lines DL1 to DLm, a first voltage line PL, a second voltage line VL1, and a third voltage line VL2. The first group of scan lines SL1 to SLn, the second group of scan lines GL1 to GLn, the third group of scan lines HL1 to HLn, and the emission lines EL1 to ELn may extend in the first direction DR1 and may be arranged in the second direction DR2 crossing the first direction DR1. The plurality of data lines DL1 to DLm may insulatively cross the first group of scan lines SL1 to SLn, the second group of scan lines GL1 to GLn, the third group of scan lines HL1 to HLn, and the emission lines EL1 to ELn.

Each of the first voltage line PL, the second voltage line VL1, and the third voltage line VL2 may include at least one of a component extending in the first direction DR1 or a component extending in the second direction DR2. Each of the first voltage line PL, the second voltage line VL1, and the third voltage line VL2 may include a component extending in the first direction DR1 and a component extending in the second direction DR2. The structures and shapes of the first voltage line PL, the second voltage line VL1, and the third voltage line VL2 may be independently designed.

Each of the plurality of pixels PX may be electrically connected to corresponding signal lines among the above-described signal lines. A connection relationship between the pixels PX and the signal lines may be changed depending on the configuration of the drive circuits of the pixels PX.

The first voltage line PL may receive a first power voltage ELVDD. A second power voltage ELVSS may be applied to the display panel 100. The second power voltage ELVSS may have a lower level than that of the first power voltage ELVDD.

The second voltage line VL1 may receive a first initialization voltage Vint. The first initialization voltage Vint may have a lower level than that of the first power voltage ELVDD. The third voltage line VL2 may receive a second initialization voltage VAint. The second initialization voltage VAint may have a lower level than that of the first power voltage ELVDD. The first initialization voltage Vint and the second initialization voltage VAint may be bias voltages having predetermined levels. The first initialization voltage Vint and the second initialization voltage VAint may have different levels. The second initialization voltage VAint may have a lower level than that of the first initialization voltage Vint.

The plurality of pixels PX may include a plurality of groups that generate light having different colors. In an embodiment, the plurality of pixels PX may include red pixels that generate red light, green pixels that generate green light, and blue pixels that generate blue light, for example. A light-emitting element of a red pixel, a light-emitting element of a green pixel, and a light-emitting element of a blue pixel may include emissive layers including different materials.

FIG. 3B illustrates a pixel PXij connected to the i^{th} scan line SLi of the first group among the first group of scan lines SL1 to SLn and connected to the j^{th} data line DLj among the plurality of data lines DL1 to DLm. That is, i may be a natural number equal to or less than n, and j may be a natural number equal to or less than m. The pixel PXij may include a pixel drive circuit PC (hereinafter, also referred to as the pixel circuit) and a light-emitting element LD.

In an embodiment, the pixel circuit PC may include first to seventh transistors T1 to T7 and a capacitor Cst. The first transistor T1, the second transistor T2, and the fifth transistor T5, the sixth transistor T6, and the seventh transistor T7 may be P-type transistors, and the third transistor T3 and the fourth transistor T4 may be N-type transistors. However, without being limited thereto, the first to seventh transistors T1 to T7 may be implemented with one of a P-type transistor or an N-type transistor.

Hereinafter, an input area (or, an input electrode) of an N-type transistor will be described as a drain (or, a drain area), an input area of a P-type transistor will be described as a source (or, a source area), an output area (or, an output electrode) of the N-type transistor will be described as a source (or, a source area), and an output area of the P-type transistor will be described as a drain (or, a drain area). At least one of the first to seventh transistors T1 to T7 may be omitted.

The first transistor T1 may be a drive transistor, and the second transistor T2 may be a switching transistor. The capacitor Cst may be electrically connected between the first voltage line PL, which receives the first power voltage ELVDD, and a reference node RN. The capacitor Cst may include a first electrode CE10 electrically connected to the reference node RN and a second electrode CE20 electrically connected to the first voltage line PL.

The first transistor T1 may be electrically connected between the first voltage line PL and one electrode (e.g., an anode) of the light-emitting element LD. A source S1 of the first transistor T1 may be electrically connected with the first voltage line PL. The expression “electrically connected between a transistor and a signal line or between a transistor and a transistor” used herein may mean that a source, a drain, and a gate of the transistor have a shape unitary with the signal line or are connected with the signal line through a connecting electrode. Another transistor may or may not be disposed between the source S1 of the first transistor T1 and the first voltage line PL.

A drain D1 of the first transistor T1 may be electrically connected with the anode of the light-emitting element LD. Another transistor may or may not be disposed between the drain D1 of the first transistor T1 and the anode of the light-emitting element LD. A gate G1 of the first transistor T1 may be electrically connected to the reference node RN.

The second transistor T2 may be electrically connected between the j^{th} data line DLj and the source S1 of the first transistor T1. A source S2 of the second transistor T2 may be electrically connected to the j^{th} data line DLj, and a drain D2 of the second transistor T2 may be electrically connected to the source Si of the first transistor T1. A gate G2 of the second transistor T2 may be electrically connected to the i^{th} scan line SLi of the first group.

The third transistor T3 may be electrically connected between the reference node RN and the drain D1 of the first transistor T1. A drain D3 of the third transistor T3 may be electrically connected to the drain D1 of the first transistor T1, and a source S3 of the third transistor T3 may be electrically connected to the reference node RN. Gates G3-1 and G3-2 of the third transistor T3 may be electrically connected to the i^{th} scan line GLi of the second group. The third transistor T3 is illustrated as including the plurality of gates. However, without being limited thereto, the third transistor T3 may include only one gate.

The fourth transistor T4 may be electrically connected between the reference node RN and the second voltage line VL1. A drain D4 of the fourth transistor T4 may be electrically connected to the reference node RN, and a source S4 of the fourth transistor T4 may be electrically connected to the second voltage line VL1. Gates G4-1 and G4-2 of the fourth transistor T4 may be electrically connected to the i^{th} scan line HLi of the third group. The fourth transistor T4 is illustrated as including the plurality of gates. However, without being limited thereto, the fourth transistor T4 may include only one gate.

The fifth transistor T5 may be electrically connected between the first voltage line PL and the source S1 of the first transistor T1. A source S5 of the fifth transistor T5 may be electrically connected to the first voltage line PL, and a drain D5 of the fifth transistor T5 may be electrically connected to the source S1 of the first transistor T1. A gate G5 of the fifth transistor T5 may be electrically connected to the i^{th} emission line ELi.

The sixth transistor T6 may be electrically connected between the drain D1 of the first transistor T1 and the light-emitting element LD. A source S6 of the sixth transistor T6 may be electrically connected to the drain D1 of the first transistor T1, and a drain D6 of the sixth transistor T6 may be electrically connected to the anode of the light-emitting element LD. A gate G6 of the sixth transistor T6 may be electrically connected to the i^{th} emission line ELi. In an alternative embodiment, the gate G6 of the sixth transistor T6 may be connected to a different signal line from the gate G5 of the fifth transistor T5.

The seventh transistor T7 may be electrically connected between the drain D6 of the sixth transistor T6 and the third voltage line VL2. A source S7 of the seventh transistor T7 may be electrically connected to the drain D6 of the sixth transistor T6, and a drain D7 of the seventh transistor T7 may be electrically connected to the third voltage line VL2. A gate G7 of the seventh transistor T7 may be electrically connected to the (i+1)^{th} scan line SLi+1 of the first group.

Operation of the pixel PXij will be described in more detail with reference to FIGS. 3B and 3C. The display device DD may display an image every frame period. During each of the frame periods, signal lines of the first group of scan lines SL1 to SLn, the second group of scan lines GL1 to GLn, the third group of scan lines HL1 to HLn, and the emission lines EL1 to ELn may be sequentially scanned. FIG. 3C illustrates a portion of any one frame period.

Referring to FIG. 3C, each of signals EMi, GIi, GWi, GCi, and GWi+1 may have a high level V-HIGH during a partial period and may have a low level V-LOW during a partial period. The N-type transistors may be turned on when corresponding signals have a high level V-HIGH, and the P-type transistors may be turned on when corresponding signals have a low level V-LOW.

When the emission control signal EMi has a high level V-HIGH, the fifth transistor T5 and the sixth transistor T6 may be turned off. When the fifth transistor T5 and the sixth transistor T6 are turned off, a current path may not be defined between the first voltage line PL and the light-emitting element LD. Accordingly, the corresponding period may be defined as a non-emission period.

When the scan signal GIi applied to the i^{th} scan line HLi of the third group has a high level V-HIGH, the fourth transistor T4 may be turned on. When the fourth transistor T4 is turned on, the reference node RN may be initialized by the first initialization voltage Vint. When the scan signal GWi applied to the i^{th} scan line SLi of the first group has a low level V-LOW and the scan signal GCi applied to the i^{th} scan line GLi of the second group has a high level V-HIGH, the second transistor T2 and the third transistor T3 may be turned on.

Because the reference node RN is initialized to the first initialization voltage Vint, the first transistor T1 may be in a turned-on state. When the first transistor T1 is turned on, a voltage corresponding to a data signal Dj (refer to FIG. 3B) may be provided to the reference node RN. At this time, the capacitor Cst may store the voltage corresponding to the data signal Dj. The voltage corresponding to the data signal Dj may be a voltage reduced by a threshold voltage Vth of the first transistor T1 from the data signal Dj.

When the scan signal GWi+1 applied to the (i+1)^{th} scan line SLi+1 of the first group has a low level V-LOW, the seventh transistor T7 may be turned on. As the seventh transistor T7 is turned on, the anode of the light-emitting element LD may be initialized to the second initialization voltage VAint. A parasitic capacitor of the light-emitting element LD may be discharged.

When the emission control signal EMi has a low level V-LOW, the fifth transistor T5 and the sixth transistor T6 may be turned on. When the fifth transistor T5 is turned on, the first power voltage ELVDD may be provided to the first transistor T1. When the sixth transistor T6 is turned on, the first transistor T1 and the light-emitting element LD may be electrically connected. The light-emitting element LD may generate light having a luminance corresponding to the amount of current provided.

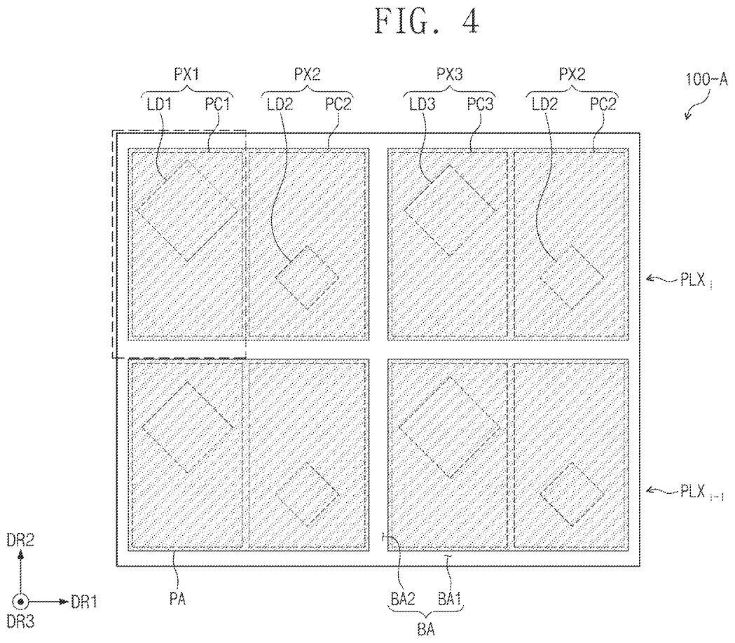

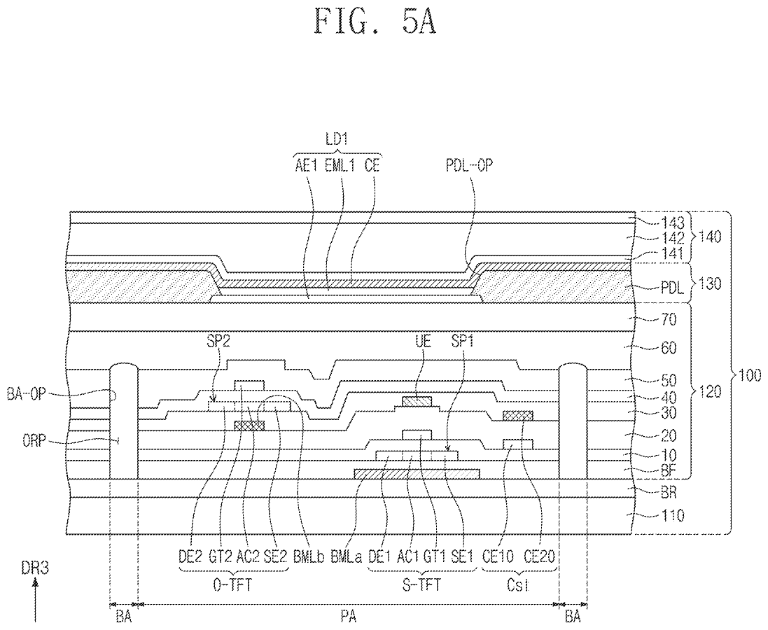

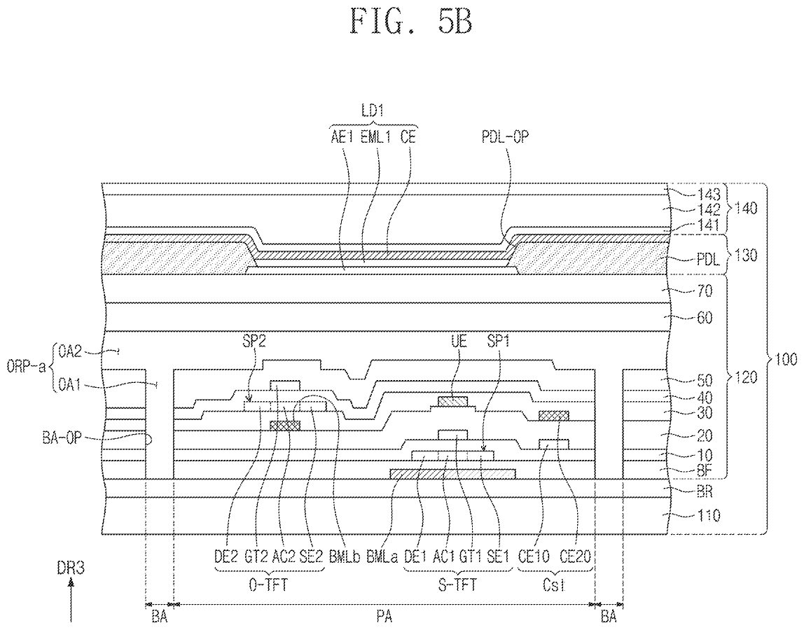

FIG. 4 is an enlarged plan view of an embodiment of the display panel 100. More specifically, FIG. 4 illustrates an enlarged view of an embodiment of the display area 100-A of the display panel 100. FIGS. 5A and 5B are cross-sectional views of an embodiment of the display panel 100.

FIG. 4 illustrates an enlarged view of two rows of pixels PLXᵢ and PLXᵢ₋₁. The i^{th} row of pixels PLXᵢ may include a first color pixel PX1, a second color pixel PX2, a third color pixel PX3, and a second color pixel PX2 arranged in the first direction DR1. Furthermore, in the i^{th} row of pixels PLXᵢ, the first color pixel PX1, the second color pixel PX2, the third color pixel PX3, and the second color pixel PX2 may be repeatedly disposed in the first direction DR1.

The (i−1)^{th} row of pixels PLXᵢ₋₁ may include a third color pixel PX3, a second color pixel PX2, a first color pixel PX1, and a second color pixel PX2 arranged in the first direction DR1. In the (i−1)^{th} row of pixels PLXᵢ₋₁, the third color pixel PX3, the second color pixel PX2, the first color pixel PX1, and the second color pixel PX2 may be repeatedly disposed in the first direction DR1. Furthermore, the color pixels in the rows of pixels PLXᵢ and PLXᵢ₋₁ illustrated in FIG. 4 may be repeatedly disposed in the second direction DR2. In FIG. 4, anodes of a first light-emitting element LD1, a second light-emitting element LD2, and a third light-emitting element LD3 are illustrated by dotted lines. FIG. 4 illustrates an embodiment in which two light-emitting elements are disposed in one pixel area PA.

The display area 100-A may include a plurality of pixel areas PA and a boundary area BA between the plurality of pixel areas PA. The boundary area BA may be disposed adjacent to at least a portion of each of the plurality of pixel areas PA. Two color pixels adjacent to each other among the first color pixel PX1, the second color pixel PX2, and the third color pixel PX3 may be surrounded by the boundary area BA. The boundary area BA may include a first boundary area BA1 extending in the first direction DR1 and a second boundary area BA2 extending in the second direction DR2.

Pixel circuits PC1, PC2, and PC3 of the first color pixel PX1, the second color pixels PX2, and the third color pixels PX3 may be disposed in the plurality of pixel areas PA. Each of the pixel circuits PC1, PC2, and PC3 may be the same as the pixel circuit PC described above with reference to FIG. 3B. Although FIG. 4 illustrates an embodiment in which the pixel circuits PC1, PC2, and PC3 substantially coincide with the pixel areas PA, the invention is not limited thereto.

The pixel areas PA may be defined as areas other than the boundary area BA in the display area 100-A. The boundary area BA may be defined by an opening BA-OP (refer to FIG. 5A) that will be described below, and the display area 100-A not overlapping the opening BA-OP may correspond to the pixel areas PA.

In FIGS. 5A and 5B, the first light-emitting element LD1, and a silicon transistor S-TFT and an oxide transistor O-TFT of the first pixel circuit PC1 (refer to FIG. 4) are illustrated. In the equivalent circuit diagram illustrated in FIG. 3B, the third and fourth transistors T3 and T4 may be oxide transistors O-TFT, and the remaining transistors T1, T2, T5, T6, and T7 may be silicon transistors S-TFT. In an alternative embodiment, the pixel circuit may include only one of the silicon transistor S-TFT and the oxide transistor O-TFT. Hereinafter, the silicon transistor S-TFT will be described as the first transistor T1 of FIG. 3B, and the oxide transistor O-TFT will be described as the third transistor T3 of FIG. 3B.

A barrier layer BR may be disposed on the base layer 110. The barrier layer BR may prevent infiltration of foreign matter from the outside. The barrier layer BR may include at least one inorganic layer. In an embodiment, the barrier layer BR may include a silicon oxide layer and/or a silicon nitride layer, for example. The silicon oxide layer and the silicon nitride layer may include a plurality of silicon oxides layers and a plurality of silicon nitride layers, respectively, and the silicon oxide layers and the silicon nitride layers may be alternately stacked.

A first shielding electrode BMLa may be disposed on the barrier layer BR. The first shielding electrode BMLa may include metal. The first shielding electrode BMLa may include molybdenum Mo having good heat resistance, an alloy including molybdenum, titanium Ti, or an alloy including titanium. The first shielding electrode BMLa may receive a bias voltage. In an embodiment, the first shielding electrode BMLa may receive the first power voltage ELVDD. The first shielding electrode BMLa may prevent electrical potential due to polarization from affecting the silicon transistor S-TFT. The first shielding electrode BMLa may prevent external light from reaching the silicon transistor S-TFT. The first shielding electrode BMLa may be a floating electrode isolated from another electrode or wiring.

A buffer layer BF may be disposed on the barrier layer BR. The buffer layer BF may prevent diffusion of metal atoms or impurities from the base layer 110 to a first semiconductor pattern SP1 disposed on the buffer layer BF. The buffer layer BF may include at least one inorganic layer. The buffer layer BF may include a silicon oxide layer and/or a silicon nitride layer.

The first semiconductor pattern SP1 may be disposed on the buffer layer BF. The first semiconductor pattern SP1 may include a silicon semiconductor. In an embodiment, the silicon semiconductor may include amorphous silicon, polycrystalline silicon, or the like, for example. More specifically, the first semiconductor pattern SP1 may include low-temperature polycrystalline silicon.

FIGS. 5A and 5B illustrate a portion of the first semiconductor pattern SP1, and the first semiconductor pattern SP1 may be additionally disposed in another area. The first semiconductor pattern SP1 may be arranged across the pixel area PA (refer to FIG. 4) according to a predetermined rule. The first semiconductor pattern SP1 may have different electrical properties depending on whether the first semiconductor pattern SP1 is doped or not. The first semiconductor pattern SP1 may include a first portion having a high conductivity and a second portion having a low conductivity. The first portion of the first semiconductor pattern SP1 may be doped with an N-type dopant or a P-type dopant. A P-type transistor may include a doped portion that is doped with a P-type dopant, and an N-type transistor may include a doped portion that is doped with an N-type dopant. The second portion of the first semiconductor pattern SP1 may be an undoped portion, or may be a portion more lightly doped than the first portion.

The first portion of the first semiconductor pattern SP1 may have a higher conductivity than the second portion of the first semiconductor pattern SP1 and may substantially serve as an electrode or a signal line. The second portion of the first semiconductor pattern SP1 may substantially correspond to a channel area (or, an active area) of a transistor. That is, a portion of the semiconductor pattern SP1 may be a channel of the transistor, another portion may be a source or a drain of the transistor, and another portion may be a connecting electrode or a connecting signal line.

A source area SE1, a channel area (or, an active area) AC1, and a drain area DE1 of the silicon transistor S-TFT may be formed or provided from the first semiconductor pattern SP1. The source area SE1 and the drain area DE1 may extend from the channel area AC1 in opposite directions on the section.

A first insulating layer 10 may be disposed on the buffer layer BF. The first insulating layer 10 may cover the first semiconductor pattern SP1. The first insulating layer 10 may be an inorganic layer. In an embodiment, the first insulating layer 10 may include at least one of aluminum oxide, titanium oxide, silicon oxide, silicon nitride, silicon oxynitride, zirconium oxide, or hafnium oxide. The first insulating layer 10 may be a signal layer including or consisting of silicon oxide. Second to fifth insulating layers 20, 30, 40, and 50 to be described below and the first insulating layer 10 may have a single layer structure or a multi-layer structure and may include at least one of the aforementioned materials. However, the invention is not limited thereto.

A gate GT1 of the silicon transistor S-TFT may be disposed on the first insulating layer 10. The gate GT1 may be a portion of a metal pattern. The gate GT1 may overlap the channel area AC1. The gate GT1 may serve as a mask in a process of doping the first semiconductor pattern SP1. The gate GT1 may include molybdenum Mo having good heat resistance, an alloy including molybdenum, titanium Ti, or an alloy including titanium, but is not limited thereto.

A first electrode CE10 of a storage capacitor Cst may be disposed on the first insulating layer 10. Unlike that illustrated in FIGS. 5A and 5B, the first electrode CE10 may have a shape unitary with the gate GT1.

The second insulating layer 20 may be disposed on the first insulating layer 10 and may cover the gate GT1. An upper electrode UE overlapping the gate GT1 may be disposed on the second insulating layer 20. A second electrode CE20 overlapping the first electrode CE10 may be disposed on the second insulating layer 20. Unlike that illustrated in FIGS. 5A and 5B, the second electrode CE20 may have a shape unitary with the upper electrode UE. The second electrode CE20 and the upper electrode UE may include molybdenum Mo having good heat resistance, an alloy including molybdenum, titanium Ti, or an alloy including titanium.

A second shielding electrode BMLb may be disposed on the second insulating layer 20. The second shielding electrode BMLb may correspond to a lower portion of the oxide transistor O-TFT. In an alternative embodiment, the second shielding electrode BMLb may be omitted. In the embodiment in which the second shielding electrode BMLb is omitted, the first shielding electrode BMLa may extend below the oxide transistor O-TFT and may replace the second shielding electrode BMLb. When the oxide transistor O-TFT includes two gates, the second shielding electrode BMLb may be a gate disposed on a lower side of the oxide transistor O-TFT.

The third insulating layer 30 may be disposed on the second insulating layer 20. A second semiconductor pattern SP2 may be disposed on the third insulating layer 30. The second semiconductor pattern SP2 may include a channel area AC2 of the oxide transistor O-TFT. The second semiconductor pattern SP2 may include an oxide semiconductor. In an embodiment, the second semiconductor pattern SP2 may include transparent conductive oxide (“TCO”) such as indium tin oxide (“ITO”), indium zinc oxide (“IZO”), indium gallium zinc oxide (“IGZO”), zinc oxide (ZnOx), or indium oxide (In₂O₃). In an embodiment, the zinc oxide (ZnOx) may include zinc oxide (ZnO) and/or zinc peroxide (ZnO₂).

The oxide semiconductor may include a plurality of areas distinguished depending on whether transparent conductive oxide is reduced or not. An area (hereinafter, referred to as the reduced area) where transparent conductive oxide is reduced may have a higher conductivity than an area (hereinafter, referred to as the non-reduced area) where transparent conductive oxide is not reduced. The reduced area may substantially serve as a source/drain of a transistor or a signal line. The non-reduced area may substantially correspond to a semiconductor area (or, a channel) of a transistor. That is, one partial area of the second semiconductor pattern SP2 may be a semiconductor area of the transistor, another partial area of the second semiconductor pattern SP2 may be a source area/drain area of the transistor, and still another partial area of the second semiconductor pattern SP2 may be a signal transmission area.

A source area SE2, a channel area (or, an active area) AC2, and a drain area DE2 of the oxide transistor O-TFT may be formed or provided from the second semiconductor pattern SP2. The source area SE2 and the drain area DE2 may extend from the channel area AC2 in opposite directions on the section.

The fourth insulating layer 40 may be disposed on the third insulating layer 30. The fourth insulating layer 40 may cover the second semiconductor pattern SP2. A gate GT2 of the oxide transistor O-TFT may be disposed on the fourth insulating layer 40. In an embodiment, the oxide transistor O-TFT may include two gates, and the two gates may include the second shielding electrode BMLb on the second insulating layer 20 and the gate GT2 on the fourth insulating layer 40. The second shielding electrode BMLb on the second insulating layer 20 and the gate GT2 on the fourth insulating layer 40 may be electrically connected.

The gate GT2 of the oxide transistor O-TFT may be a portion of a metal pattern. The gate GT2 of the oxide transistor O-TFT may overlap the channel area AC2. The gate GT2 may include molybdenum Mo having good heat resistance, an alloy including molybdenum, titanium Ti, or an alloy including titanium. The gate GT2 may include a titanium layer and a molybdenum layer disposed on the titanium layer.

The fifth insulating layer 50 may be disposed on the fourth insulating layer 40 and may cover the gate GT2. Each of the first to fifth insulating layers 10, 20, 30, 40, and 50 may be an inorganic layer.

The buffer layer BF and the first to fifth insulating layers 10, 20, 30, 40, and 50 may be defined as a stack structure of inorganic materials. The opening BA-OP may be defined in the stack structure of the inorganic materials. The opening BA-OP may correspond to the boundary area BA described above with reference to FIG. 4.

The stack structure of the inorganic materials may be divided into a plurality of islands to correspond to the plurality of pixels PX1, PX2, and PX3 illustrated in FIG. 4. Each of the plurality of islands may include at least one pixel area and a boundary area surrounding the at least one pixel area. The plurality of islands may disperse external impact and may thus prevent cracks in the stack structure of the inorganic materials due to the external impact.

In an embodiment, an organic layer ORP may fill the opening BA-OP. The organic layer ORP may have a closed-line shape in a plan view. In an embodiment, the organic layer ORP may have a closed-line shape surrounding the pixel area PA, for example.

Organic insulating layers 60 and 70 may be disposed on the fifth insulating layer 50. The first organic insulating layer 60 may be disposed on the fifth insulating layer 50, and the second organic insulating layer 70 may be disposed on the first organic insulating layer 60.

The first organic insulating layer 60 may remove a step of the fifth insulating layer 50 disposed under the first organic insulating layer 60 and may form a flat upper surface. The first organic insulating layer 60 may cover the organic layer ORP. The first organic insulating layer 60 may contact the organic layer ORP and the fifth insulating layer 50. The first organic insulating layer 60 may overlap an entirety of the base layer 110.

In an embodiment, each of the first organic insulating layer 60 and the second organic insulating layer 70 may include a general purpose polymer, such as benzocyclobutene (“BCB”), polyimide, hexamethyldisiloxane (“HMDSO”), polymethylmethacrylate (“PMMA”), or polystyrene (“PS”), a polymer derivative having a phenolic group, an acrylate-based polymer, an imide-based polymer, an aryl ether-based polymer, an amide-based polymer, a fluorine-based polymer, a p-xylene-based polymer, a vynyl alcohol-based polymer, or a combination thereof.

Although not illustrated, a plurality of conductive patterns may be disposed between the fifth insulating layer 50 and the first organic insulating layer 60. Furthermore, a plurality of conductive patterns may be disposed between the first organic insulating layer 60 and the second organic insulating layer 70. The conductive patterns will be described below in more detail.

A first electrode AE1 of the first light-emitting element LD1 may be disposed on the second organic insulating layer 70. The first light-emitting element LD1 may include the first electrode AE1, an emissive layer EML1, and a second electrode (or, a common electrode) CE. The second electrode of the first light-emitting element LD1 and the second electrode of the third light-emitting element LD3 described above with reference to FIG. 4 may have a shape unitary with the second electrode CE of the first light-emitting element LD1. That is, the second electrode CE may be commonly provided to the first light-emitting element LD1, the second light-emitting element LD2, and the third light-emitting element LD3.

The first electrode AE1 may be a transparent electrode, a translucent electrode, or a reflective electrode. The first electrode AE1 may include a reflective layer including Ag, Mg, Al, Pt, Pd, Au, Ni, Nd, Ir, Cr, or a combination thereof and a transparent or translucent electrode layer formed or disposed on the reflective layer. The transparent or translucent electrode layer may include at least one of ITO, IZO, IGZO, zinc oxide (ZnOx), indium oxide (In₂O₃) and aluminum-doped zinc oxide (“AZO”). In an embodiment, the first electrode AE1 may include a three-layer structure of ITO/Ag/ITO, for example, but is not limited thereto.

A pixel defining film PDL may be disposed on the second organic insulating layer 70. The pixel defining film PDL may have a property of being transparent, or may have a property of absorbing light. In an embodiment, the pixel defining film PDL that absorbs light may include a black coloring agent, for example. The black coloring agent may include a black dye or a black pigment. In an embodiment, the black coloring agent may include carbon black, metal such as chromium, or oxide thereof. The pixel defining film PDL may correspond to a shielding pattern having light-blocking characteristics.

The pixel defining film PDL may cover a portion of the first electrode AE1. In an embodiment, an opening PDL-OP for exposing the portion of the first electrode AE1 may be defined in the pixel defining film PDL, for example. The pixel defining film PDL may increase the distance between the periphery of the first electrode AE1 and the second electrode CE. Accordingly, the pixel defining film PDL may serve to prevent an arc from occurring at the periphery of the first electrode AE1.

Although not illustrated, a hole transporting layer may be disposed between the first electrode AE1 and the emissive layer EML1. Furthermore, a hole injection layer may be disposed between the first electrode AE1 and the hold transporting layer. An electron transporting layer may be disposed between the emissive layer EML1 and the second electrode CE. An electron injection layer may be disposed between the electron transporting layer and the second electrode CE. The hole transporting layer, the hole injection layer, the electron transporting layer, and the electron injection layer may each be commonly formed or provided in the plurality of rows of pixels PLXᵢ and PLXᵢ₋₁ (refer to FIG. 4).

The encapsulation layer 140 may be disposed on the light-emitting element layer 130. The encapsulation layer 140 may include an inorganic encapsulation layer 141, an organic encapsulation layer 142, and an inorganic encapsulation layer 143 sequentially stacked one above another. However, layers constituting the encapsulation layer 140 are not limited thereto.

The inorganic encapsulation layers 141 and 143 may protect the light-emitting element layer 130 for moisture and oxygen, and the organic encapsulation layer 142 may protect the light-emitting element layer 130 from foreign matter such as dust particles. In an embodiment, the inorganic encapsulation layers 141 and 143 may include a silicon nitride layer, a silicon oxynitride layer, a silicon oxide layer, a titanium oxide layer, or an aluminum oxide layer. The organic encapsulation layer 142 may include, but is not limited to, an acrylate-based organic layer.

Unlike in FIG. 5A, an organic layer ORP-a including a first portion OA1 and a second portion OA2 is illustrated in FIG. 5B. In an embodiment, the organic layer ORP-a may include the first portion OA1 that fills the opening BA-OP corresponding to the boundary area BA. Furthermore, the organic layer ORP-a may include the second portion OA2 extending from the first portion OA1 and overlapping the pixel area PA and the boundary area BA. In FIG. 5A, the organic layer ORP that includes the first portion OA1 and does not include the second portion OA2 is illustrated.

The second portion OA2 of the organic layer ORP-a may be disposed on the fifth insulating layer 50 that is the uppermost inorganic insulating layer included in the circuit layer 120. The second portion OA2 may have a shape unitary with the first portion OA1. The second portion OA2 may overlap an entirety of the base layer 110. The second portion OA2 may remove steps of the insulating layers 10, 20, 30, 40, and 50 disposed under the second portion OA2 and may form a flat upper surface.

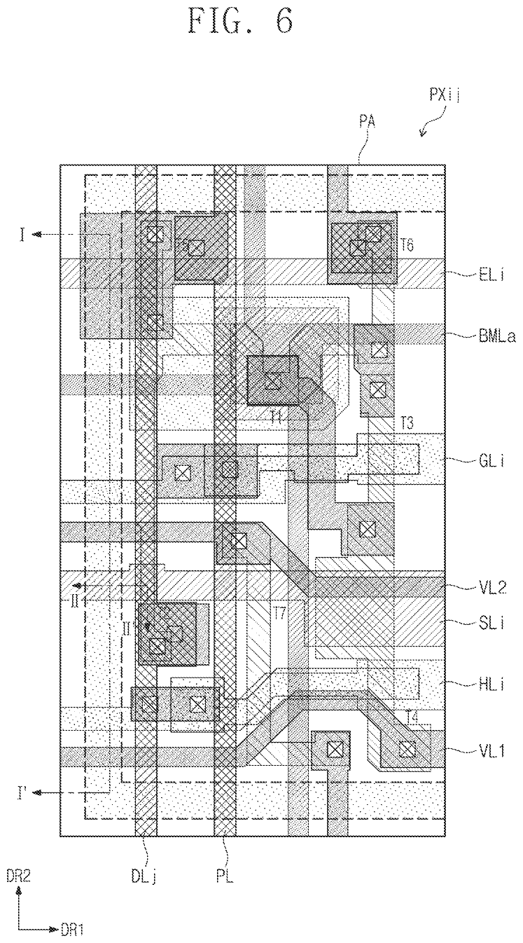

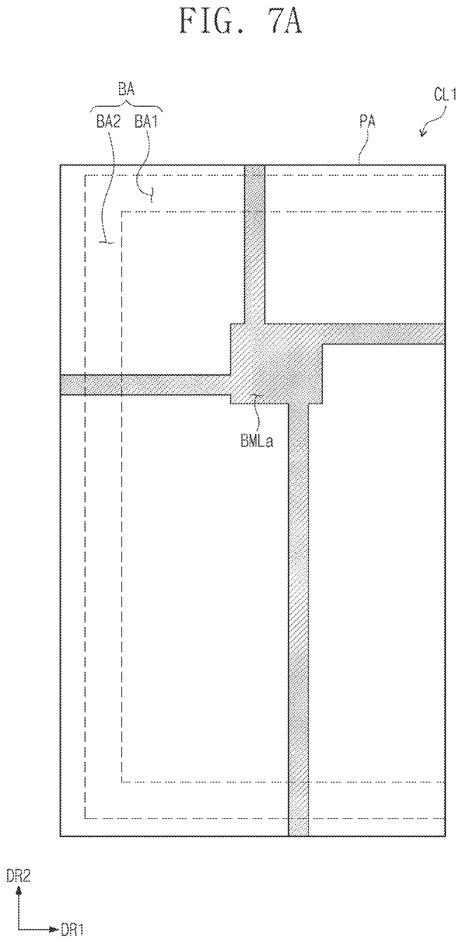

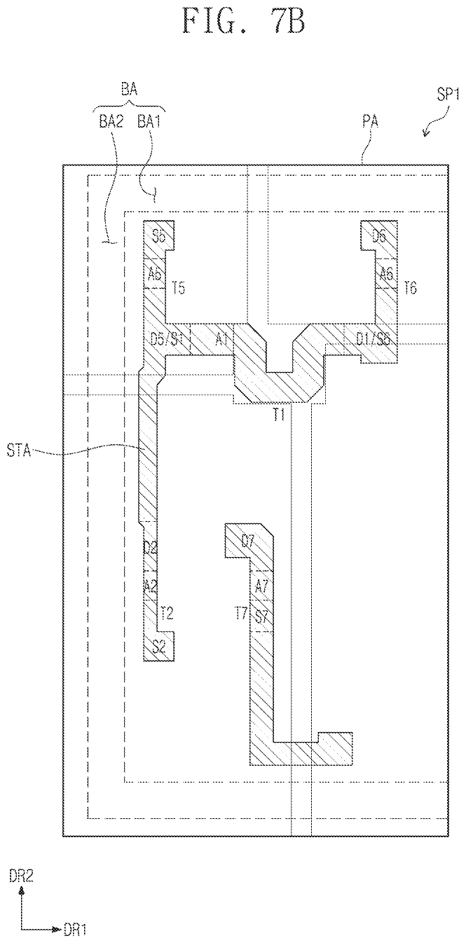

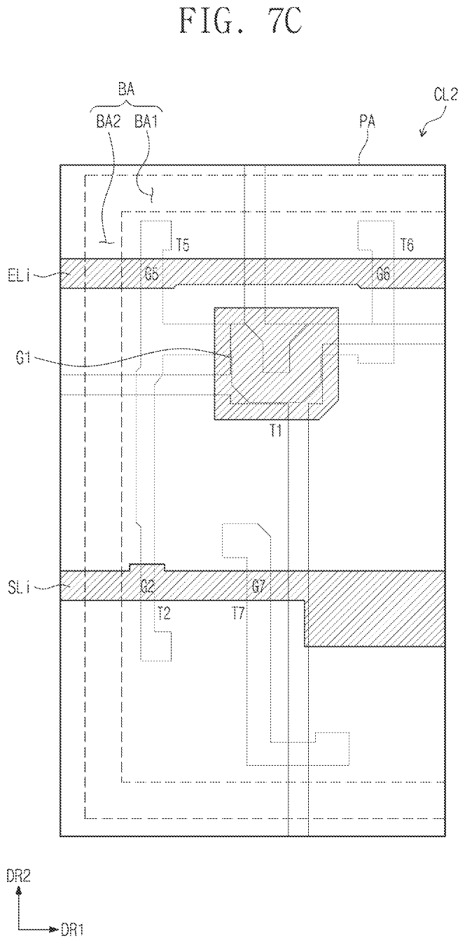

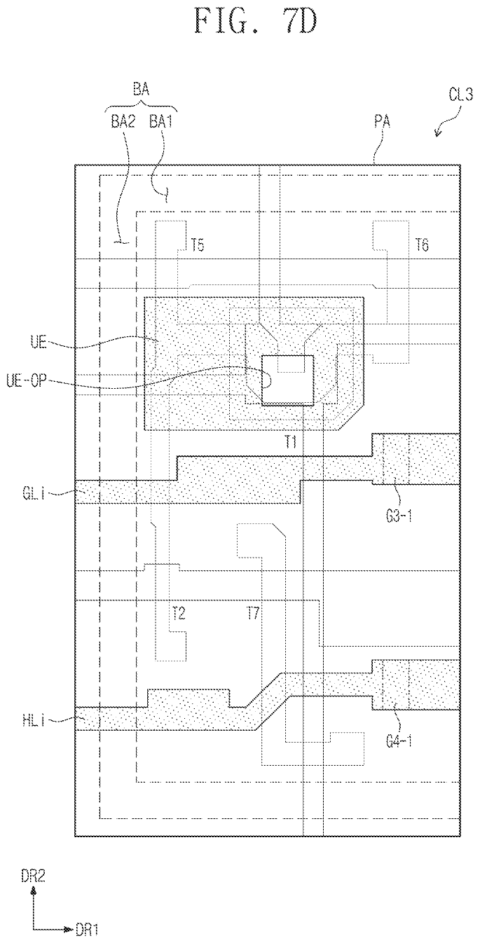

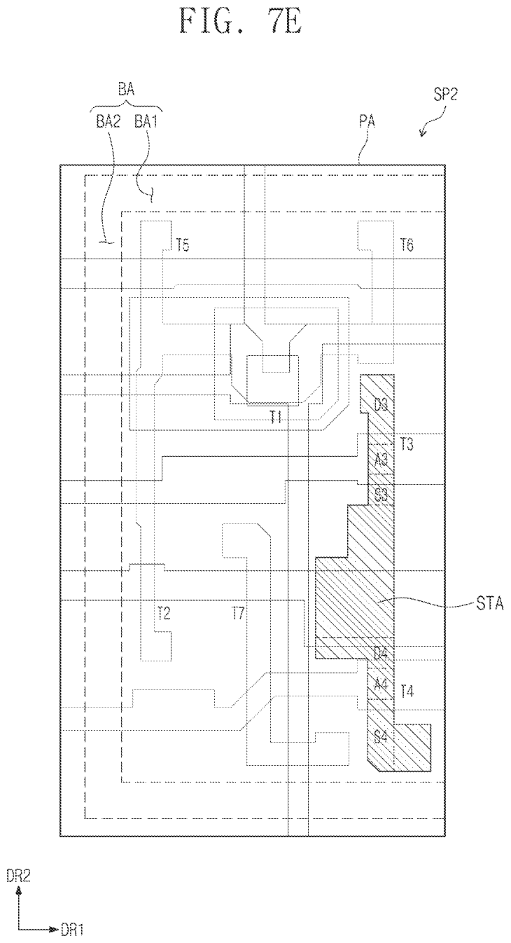

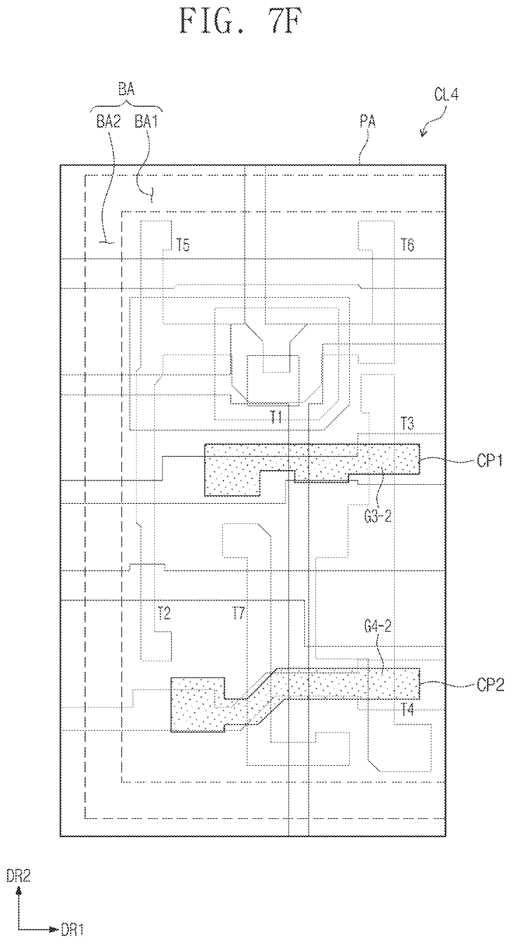

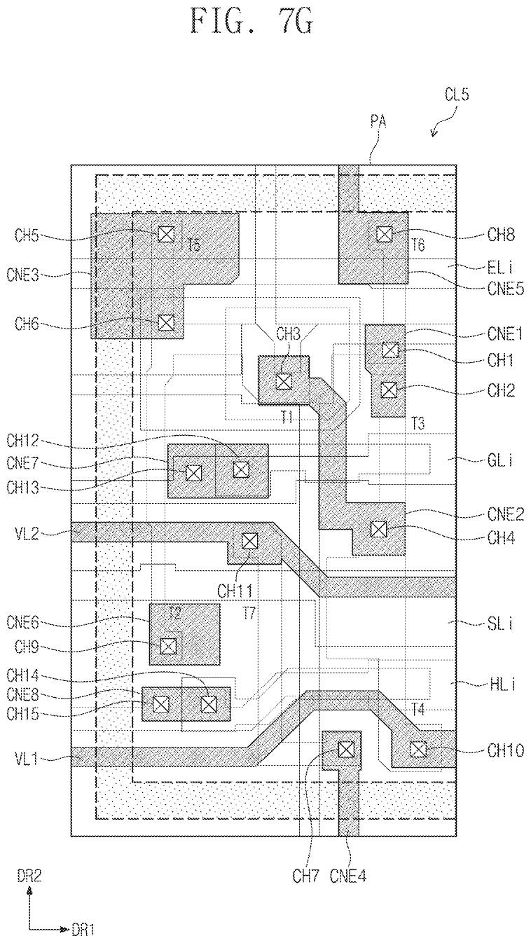

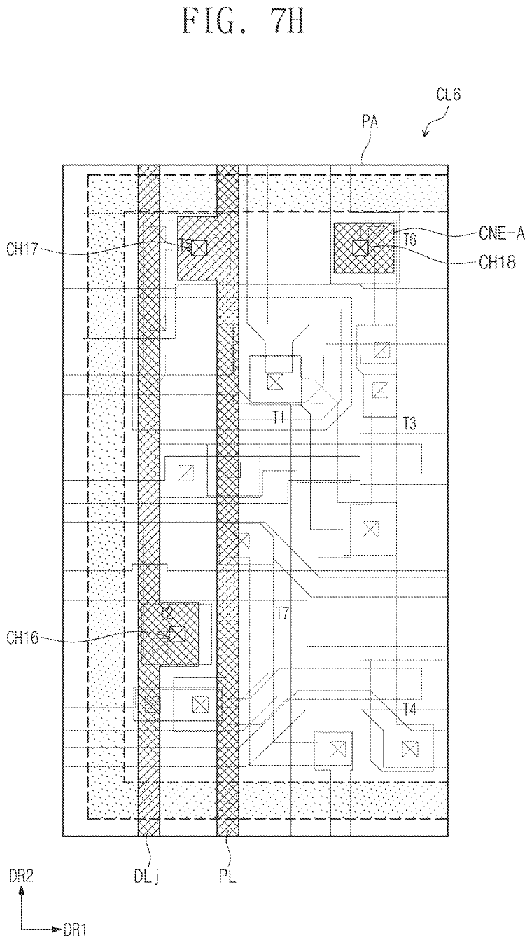

FIG. 6 is a plan view of an embodiment of the pixel area PA. FIGS. 7A to 7H are plan views illustrating components in the pixel area PA in a stacking order.

Referring to FIG. 7A, a first conductive layer CL1 may be disposed on the barrier layer BR (refer to FIG. 5A). The first conductive layer CL1 may include the first shielding electrode BMLa. The first shielding electrode BMLa may include a portion extending in the first direction DR1 and a portion extending in the second direction DR2. The portion of the first shielding electrode BMLa that extends in the first direction DR1 may overlap the second boundary area BA2, and the portion of the first shielding electrode BMLa that extends in the second direction DR2 may overlap the first boundary area BA1.

Referring to FIG. 7B, the first semiconductor pattern SP1 may be disposed on the barrier layer BR (refer to FIG. 5A). In FIG. 7B, two first semiconductor patterns SP1 are illustrated.

The first semiconductor pattern SP1 may include a plurality of areas having different doping concentrations. The first semiconductor pattern SP1 may include source areas S1, S2, S5, S6, and S7, channel areas A1, A2, A5, A6, and A7, and drain areas D1, D2, D5, D6, and D7 of first, second, fifth, sixth, and seventh transistors T1, T2, T5, T6, and T7. The first semiconductor pattern SP1 may further include a signal transmission area STA. The source areas S1, S2, S5, S6, and S7 and the drain areas D1, D2, D5, D6, and D7 may correspond to the sources S1, S2, S5, S6, and S7 and the drains D1, D2, D5, D6, and D7 described above with reference to FIG. 3B.

In FIG. 7B, for convenience of description, the source areas S1, S2, S5, S6, and S7 and the drain areas D1, D2, D5, D6, and D7 of adjacent semiconductor areas are separately illustrated. Furthermore, although the signal transmission area STA is additionally illustrated, the invention is not limited thereto. Substantially, the signal transmission area STA may be an area having the same doping concentration as the source areas S1, S2, S5, S6, and S7 or the drain areas D1, D2, D5, D6, and D7 and may not be distinguished from the source areas S1, S2, S5, S6, and S7 or the drain areas D1, D2, D5, D6, and D7.

Referring to FIG. 7C, a second conductive layer CL2 may be disposed on the first insulating layer 10 (refer to FIG. 5A). The second conductive layer CL2 may include a plurality of conductive patterns.

The second conductive layer CL2 may include the gate G1 of the first transistor T1, the i^{th} scan line SLi of the first group, and the i^{th} emission line ELi. The i^{th} scan line SLi of the first group and the i^{th} emission line ELi may extend in the first direction DR1. The i^{th} scan line SLi of the first group and the i^{th} emission line ELi that extend in the first direction DR1 may overlap the boundary area BA and the pixel area PA. More specifically, the i^{th} scan line SLi of the first group and the i^{th} emission line ELi that extend in the first direction DR1 may overlap the second boundary area BA2. The i^{th} scan line SLi of the first group and the i^{th} emission line ELi may extend to an adjacent pixel area.

In an embodiment, the i^{th} scan line SLi of the first group and the i^{th} emission line ELi may each have a multi-layer structure, for example. The i^{th} scan line SLi of the first group and the i^{th} emission line ELi may each include an aluminum layer and a titanium layer disposed on the aluminum layer.

One portion of the i^{th} scan line SLi of the first group that overlaps the first semiconductor pattern SP1 may be the gate G2 of the second transistor T2, and another portion of the i^{th} scan line SLi of the first group that overlaps the first semiconductor pattern SP1 may be the gate G7 of the seventh transistor T7. However, the seventh transistor T7 may initialize the light-emitting elements in the (i−1)^{th} row of pixels PLXᵢ₋₁ (refer to FIG. 4). The light-emitting elements in the i^{th} row of pixels PLXᵢ (refer to FIG. 4) may be initialized by a seventh transistor T7 disposed in the non-illustrated (i+1)^{th} row of pixels.

One portion of the i^{th} emission line ELi that overlaps the first semiconductor pattern SP1 may be the gate G5 of the fifth transistor T5, and another portion of the i^{th} emission line ELi that overlaps the first semiconductor pattern SP1 may be the gate G6 of the sixth transistor T6.

After the conductive patterns of the second conductive layer CL2 are formed or provided, a doping process may be performed on the first semiconductor pattern SP1 (refer to FIG. 7B). The source areas S1, S2, S5, S6, and S7, the channel areas A1, A2, A5, A6, and A7, and the drain areas D1, D2, D5, D6, and D7 illustrated in FIG. 7B may be distinguished from one another by the doping process.

Referring to FIG. 7D, a third conductive layer CL3 may be disposed on the second insulating layer 20 (refer to FIG. 5A). The third conductive layer CL3 may include the upper electrode UE, the i^{th} scan line GLi of the second group, and the i^{th} scan line HLi of the third group.

An opening UE-OP may be defined in the upper electrode UE. The i^{th} scan line GLi of the second group and the i^{th} scan line HLi of the third group may extend in the first direction DR1 and may overlap the boundary area BA and the pixel area PA. More specifically, the i^{th} scan line GLi of the second group and the i^{th} scan line HLi of the third group may extend in the first direction DR1 and may overlap the second boundary area BA2. The i^{th} scan line GLi of the second group and the i^{th} scan line HLi of the third group may extend to an adjacent pixel area.

In an embodiment, the i^{th} scan line GLi of the second group and the i^{th} scan line HLi of the third group may each have a multi-layer structure, for example. The i^{th} scan line GLi of the second group and the i^{th} scan line HLi of the third group may each include an aluminum layer and a titanium layer disposed on the aluminum layer.

One portion of the i^{th} scan line GLi of the second group may be a 3-1 gate G3-1 of the third transistor T3, and one portion of the i^{th} scan line HLi of the third group may be a 4-1 gate G4-1 of the fourth transistor T4. Furthermore, the 3-1 gate G3-1 and the 4-1 gate G4-1 may be replaced with the second shielding electrode BMLb (refer to FIG. 5A).

Referring to FIG. 7E, the second semiconductor pattern SP2 may be disposed on the third insulating layer 30 (refer to FIG. 5A). In FIG. 7E, one second semiconductor patterns SP2 is illustrated.

The second semiconductor pattern SP2 may include a plurality of areas distinguished depending on whether metal oxide is reduced or not. The second semiconductor pattern SP2 may include source areas S3 and S4, channel areas A3 and A4, and drain areas D3 and D3 of the third and fourth transistors T3 and T4.

Referring to FIG. 7F, a fourth conductive layer CL4 may be disposed on the fourth insulating layer 40 (refer to FIG. 5A). The fourth conductive layer CL4 may include a first conductive pattern CP1 and a second conductive pattern CP2. The first conductive pattern CP1 and the second conductive pattern CP2 may include the gate GT2 of the oxide transistor O-TFT (refer to FIG. 5A). The first conductive pattern CP1 may include an upper gate of the third transistor T3, and the second conductive pattern CP2 may include an upper gate of the fourth transistor T4. More specifically, the first conductive pattern CP1 may include the gate G3-2 overlapping the channel area A3 of the third transistor T3. The second conductive pattern CP2 may include the gate G4-2 overlapping the channel area A4 of the fourth transistor T4. After the conductive patterns of the fourth conductive layer CL4 are formed or provided, a doping process (or, a reduction process) may be performed on the second semiconductor pattern SP2.

Referring to FIG. 7G, a fifth conductive layer CL5 may be disposed on the fifth insulating layer 50 (refer to FIG. 5A). The fifth conductive layer CL5 may include a plurality of conductive patterns.

Before the formation of the fifth conductive layer CL5, the opening BA-OP may be defined to correspond to the boundary area BA illustrated in FIGS. 4 and 5A, and the organic layer ORP may fill the opening BA-OP. The opening BA-OP may be defined by etching the buffer layer BF and the insulating layers 10, 20, 30, 40, and 50. When the organic layer ORP-a includes the first portion OA1 and the second portion OA2 as illustrated in FIG. 5B, the first portion OA1 and the second portion OA2 may be formed or provided through the same process. However, without being limited thereto, the first portion OA1 and the second portion OA2 may be formed or provided through separate processes.

The fifth conductive layer CL5 may include the second voltage line VL1 and the third voltage line VL2. Each of the second voltage line VL1 and the third voltage line VL2 may extend in the first direction DR1 and may overlap the boundary area BA and the pixel area PA. Furthermore, the fifth conductive layer CL5 may include a plurality of connecting electrodes, and a plurality of contact holes may be defined in the fifth conductive layer CL5.

A first connecting electrode CNE1 may connect the drain area D1 (refer to FIG. 7B) of the first transistor T1 and the drain area D3 (refer to FIG. 7E) of the third transistor T3 through a first contact hole CH1 and a second contact hole CH2. A second connecting electrode CNE2 may connect the gate G1 (refer to FIG. 7B) of the first transistor T1 and the source area S3 (refer to FIG. 7E) of the third transistor T3 through a third contact hole CH3 and a fourth contact hole CH4. A third connecting electrode CNE3 may connect the source area S5 (refer to FIG. 7B) of the fifth transistor T5 and the upper electrode UE (refer to FIG. 7D) through a fifth contact hole CH5 and a sixth contact hole CH6.

A fourth connecting electrode CNE4 may be connected to the source area S7 (refer to FIG. 7B) of the seventh transistor T7 through a seventh contact hole CH7. The fourth connecting electrode CNE4 may be electrically connected with an anode of a non-illustrated light-emitting element LD in the (i−1)^{th} row of pixels PLXᵢ₋₁. A fifth connecting electrode CNE5 may be connected to the drain area D6 (refer to FIG. 7B) of the sixth transistor T6 through an eighth contact hole CH8. The fifth connecting electrode CNE5 may be connected to a source area of a seventh transistor in the non-illustrated (i+1)^{th} row of pixels.

A sixth connecting electrode CNE6 may be connected to the source area S2 (refer to FIG. 7B) of the second transistor T2 through a ninth contact hole CH9. The second voltage line VL1 may be connected to the source area S4 (refer to FIG. 7E) of the fourth transistor T4 through a tenth contact hole CH10. The third voltage line VL2 may be connected to the drain area D7 (refer to FIG. 7B) of the seventh transistor T7 through an eleventh contact hole CH11. The tenth contact hole CH10 and the eleventh contact hole CH11 may penetrate the fifth insulating layer 50 (refer to FIG. 5A).

A seventh connecting electrode CNE7 may be connected to the first conductive pattern CP1 through a twelfth contact hole CH12. More specifically, the seventh connecting electrode CNE7 may be connected, through the twelfth contact hole CH12, to the gate G3-2 overlapping the channel area A3 of the third transistor T3 formed or provided from the first conductive pattern CP1. Furthermore, the seventh connecting electrode CNE7 may be connected to the i^{th} scan line GLi of the second group through a thirteenth contact hole CH13.

An eighth connecting electrode CNE8 may be connected to the second conductive pattern CP2 through a fourteenth contact hole CH14. More specifically, the eighth connecting electrode CNE8 may be connected, through the fourteenth contact hole CH14, to the gate G4-2 overlapping the channel area A4 of the fourth transistor T4 formed or provided from the second conductive pattern CP2. Furthermore, the eighth connecting electrode CNE8 may be connected to the i^{th} scan line HLi of the third group through a fifteenth contact hole CH15.

Referring to FIG. 7H, a sixth conductive layer CL6 may be disposed on the first organic insulating layer 60 (refer to FIG. 5A). The sixth conductive layer CL6 may include a plurality of conductive patterns. The sixth conductive layer CL6 may include the i^{th} data line DLj, the first voltage line PL, and a ninth connecting electrode CNE-A. The i^{th} data line DLj and the first voltage line PL may extend in the second direction DR2. The i^{th} data line DLj and the first voltage line PL may overlap the first boundary area BA1 and the pixel area PA.

The i^{th} data line DLj may be connected to the sixth connecting electrode CNE6 (refer to FIG. 7G) through a sixteenth contact hole CH16. The first voltage line PL may be connected to the third connecting electrode CNE3 (refer to FIG. 7G) through a seventeenth contact hole CH17. The ninth connecting electrode CNE-A may be connected to the fifth connecting electrode CNE5 (refer to FIG. 7G) through an eighteenth contact hole CH18. The sixteenth to eighteenth contact holes CH16 to CH18 may penetrate the first organic insulating layer 60 (refer to FIG. 5A). Although not illustrated, the first electrode AE1 (refer to FIG. 5A) may be disposed on the second organic insulating layer 70 (refer to FIG. 5A) and may be connected to the ninth connecting electrode CNE-A through a contact hole penetrating the second organic insulating layer 70 (refer to FIG. 5A).

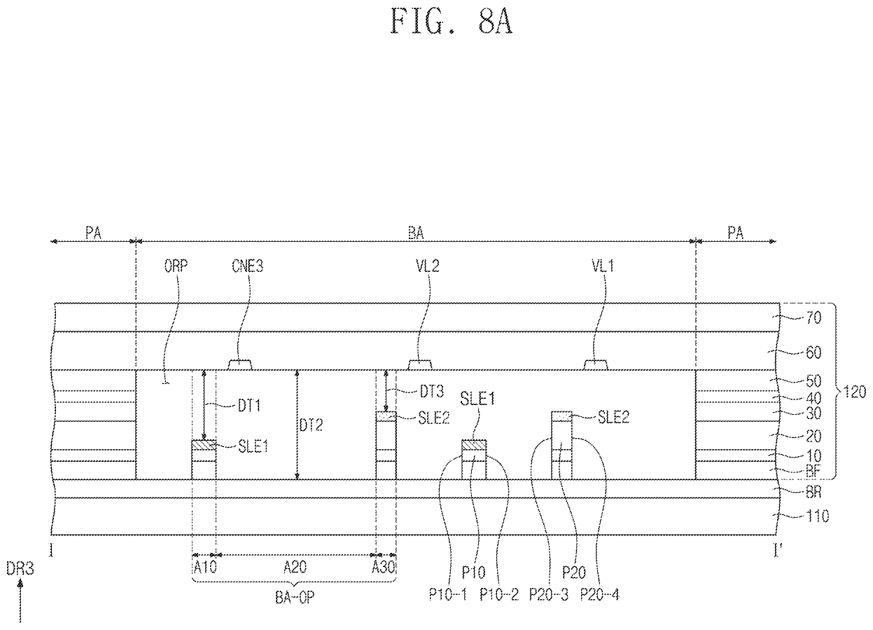

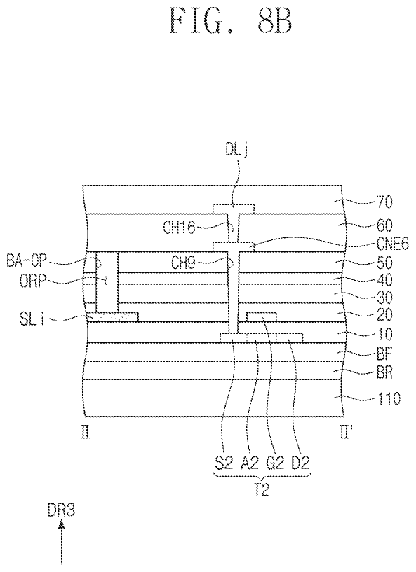

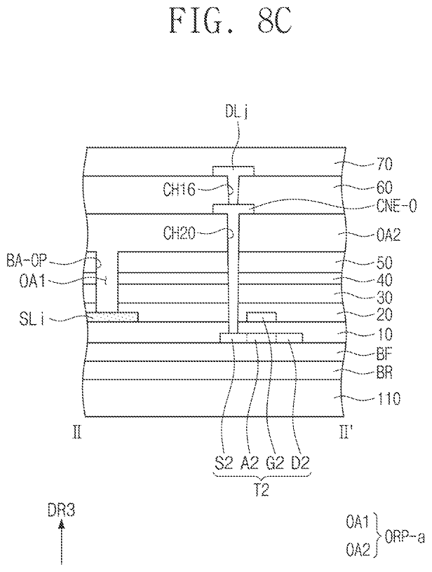

FIG. 8A is a cross-sectional view illustrating a portion corresponding to line I-I′ of FIG. 6. In an embodiment, a first signal line SLE1 may be disposed on the first insulating layer 10. In FIG. 8A, one of two first signal lines SLE1 may be the emission line ELi (refer to FIG. 6), and the other may be the i^{th} scan line SLi (refer to FIG. 6) of the first group. The first signal line SLE1 may be covered by the second insulating layer 20. An upper portion of the first signal line SLE1 may contact the second insulating layer 20.

A second signal line SLE2 may be disposed on the second insulating layer 20. In FIG. 8A, one of two second signal lines SLE2 may be the i^{th} scan line GLi (refer to FIG. 6) of the second group, and the other may be the i^{th} scan line HLi (refer to FIG. 6) of the third group. The third insulating layer 30 may cover the second signal line SLE2. An upper portion of the second signal line SLE2 may contact the third insulating layer 30.

Referring to FIG. 8A, the opening BA-OP may include a first area A10 having a first depth DH1 and a second area A20 having a second depth DH2. The first depth DH1 of the first area A10 may be smaller than the second depth DH2 of the second area A20. The first area A10 may overlap the first signal line SLE1. More specifically, the first area A10 may overlap the buffer layer BF, the first insulating layer 10 disposed on the buffer layer BF, and the first signal line SLE1 disposed on the first insulating layer 10. The first area A10 may penetrate the second insulating layer 20 and the third insulating layer 30 over the first signal line SLE1. Furthermore, the first area A10 may penetrate the fourth insulating layer 40 and the fifth insulating layer 50 that are disposed on the third insulating layer 30.

The second area A20 may not overlap the first signal line SLE1 and the second signal line SLE2. In the second area A20, the barrier layer BR may be exposed. In the second area A20, the organic layer ORP and the barrier layer BR may contact each other. The second area A20 may penetrate the buffer layer BF and the first to third insulating layers 10, 20, and 30. Furthermore, the second area A20 may penetrate the fourth insulating layer 40 and the fifth insulating layer 50. An opening may be defined in the third insulating layer 30, and the fourth insulating layer 40 and the fifth insulating layer 50 disposed on the third insulating layer 30 to have substantially the same depth.

The organic layer ORP filling the opening BA-OP may contact the first signal line SLE1. More specifically, in the first area A10, a lower surface of the organic layer ORP may contact the first signal line SLE1. In an embodiment, the display panel 100 may include the plurality of insulating layers BF and 10 to 50, and the opening BA-OP may be defined in the plurality of insulating layers BF and 10 to 50. The organic layer ORP may fill the opening BA-OP including the first area A10 and the second area A20.

The first insulating layer 10 may include a first insulating portion P10 overlapping the boundary area BA. A first opening P10-1 and a second opening P10-2 may be defined in the first insulating layer 10 with the first insulating portion P10 therebetween. The second insulating layer 20 may include a second insulating portion P20 overlapping the boundary area BA. A third opening P20-3 and a fourth opening P20-4 may be defined in the second insulating layer 20 with the second insulating portion P20 therebetween.

The first to fourth openings P10-1, P10-2, P20-3, and P20-4 may constitute portions of the opening BA-OP. The first opening P10-1 and the second opening P10-2 may constitute the second area A20 of the opening BA-OP. The third opening P20-3 and the fourth opening P20-4 may constitute the second area A20 of the opening BA-OP. That is, the opening BA-OP filled with the organic layer ORP may be constituted from the openings P10-1, P10-2, P20-3, and P20-4 of the insulating layers 10, 20, 30, 40, and 50. The openings P10-1, P10-2, P20-3, and P20-4 of the insulating layers 10, 20, 30, 40, and 50 may be gathered to define the opening BA-OP filled with the organic layer ORP.

The opening BA-OP in an embodiment may include a third area A30 overlapping the second signal line SLE2. The third area A30 may have a third depth DH3, and the third depth DH3 may be smaller than the first depth DH1. The third area A30 may be spaced apart from the first area A10 with the second area A20 therebetween. The organic layer ORP filling the opening BA-OP may contact the second signal line SLE2. More specifically, in the third area A30, the lower surface of the organic layer ORP may contact the second signal line SLE2.

As the first area A10, the second area A20, and the third area A30 of the opening BA-OP have different depths DH1, DH2, and DH3, the organic layer ORP filling the opening BA-OP may have different thicknesses. That is, the thickness of the organic layer ORP may not be constant on the section parallel to the thickness direction.

In the display panel 100 in an embodiment, the organic layer ORP may fill the opening BA-OP. The opening BA-OP may include the first area A10 that is defined to correspond to the boundary area BA and that overlaps the first signal line SLE1 and has the first depth DH1 and the second area A20 having the second depth DH2 greater than the first depth DH1. The first signal line SLE1 overlapping the opening BA-OP may overlap the boundary area BA and the pixel area PA and may extend in one direction (e.g., the first direction). Accordingly, a signal line may be unitary in adjacent pixel areas PA. That is, in the display panel 100, the data line DLj and the signal lines SLE1 and SLE2 may not be divided for each pixel area PA, and therefore an additional metal layer for connecting divided signal lines may be omitted. Accordingly, time and cost of a process of manufacturing the display panel 100 may be reduced. The display panel 100 in an embodiment may achieve improved manufacturing efficiency.

FIG. 8B is a cross-sectional view illustrating a portion corresponding to line II-IF of FIG. 6. Referring to FIG. 8B, the i^{th} data line DLj disposed on the second organic insulating layer 70 may be electrically connected to the second transistor T2 disposed on the first insulating layer 10. As described above, the i^{th} data line DLj may be connected to the source S2 of the second transistor T2 through a contact hole. More specifically, the i^{th} data line DLj may be connected to the sixth connecting electrode CNE6 through the sixteenth contact hole CH16, and the sixth connecting electrode CNE6 may be connected to the source S2 of the second transistor T2 through the ninth contact hole CH9. The sixteenth contact hole CH16 may penetrate the first organic insulating layer 60. The sixth connecting electrode CNE6 may be disposed on the fifth insulating layer 50, and the ninth contact hole CH9 may penetrate the first to fifth insulating layers 10, 20, 30, 40, and 50. Although not illustrated, the first shielding electrode BMLa (refer to FIG. 5A) may be disposed under the second transistor T2.

Unlike that illustrated in FIG. 8B, the second portion OA2 of the organic layer ORP-a is illustrated in FIG. 8C as being disposed on the fifth insulating layer 50. The organic insulating layers 60 and 70 may be disposed on the second portion OA2. The j^{th} data line DLj may be connected to a tenth connecting electrode CNE-O through the sixteenth contact hole CH16, and the tenth connecting electrode CNE-O may be electrically connected to the source S2 of the second transistor T2 through a twentieth contact hole CH20. The sixteenth contact hole CH16 may penetrate the second portion OA2, and the twentieth contact hole CH20 may penetrate the second portion OA2 and the first to fifth insulating layers 10, 20, 30, 40, and 50.

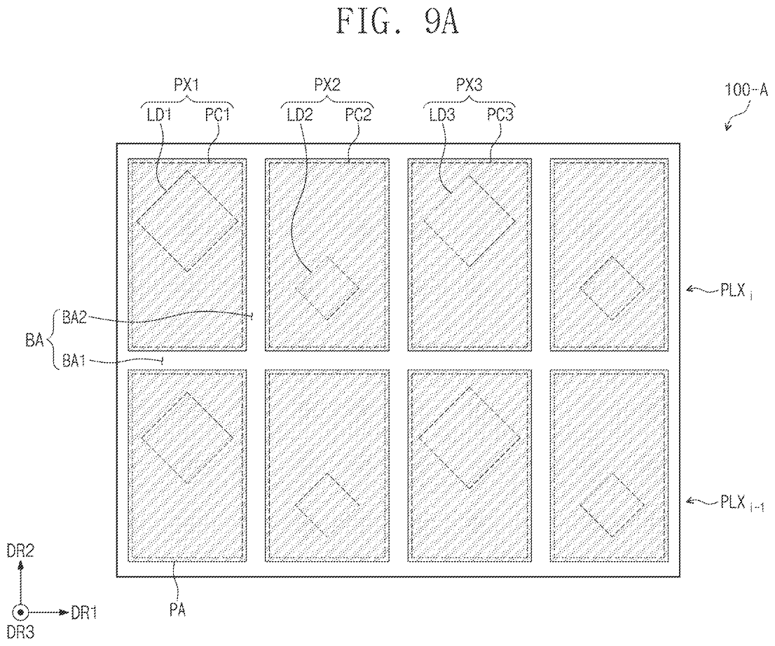

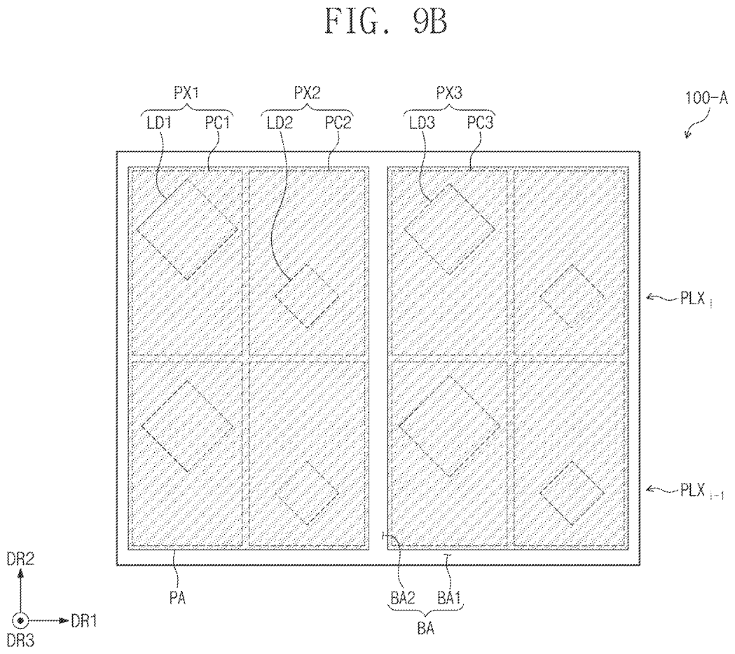

FIGS. 9A and 9B are enlarged plan views of an embodiment of the display panel 100. FIG. 9A illustrates an embodiment in which one light-emitting element is disposed in one pixel area PA, and FIG. 9B illustrates an embodiment in which four light-emitting elements are disposed in one pixel area PA.

As illustrated in FIG. 9A, one of a first color pixel PX1, a second color pixel PX2, and a third color pixel PX3 may be disposed in each of pixel areas PA, and the pixel areas PA may be surrounded by a boundary area BA. That is, FIG. 9A illustrates an embodiment in which one pixel is disposed in one pixel area PA. Furthermore, unlike in FIG. 4, the first color pixel PX1 and the second color pixel PX2 may be spaced apart from each other with a second boundary area BA2 therebetween.

As illustrated in FIG. 9B, one first color pixel PX1, one third color pixel PX3, and two second color pixels PX2 may be disposed in one pixel area PA. Pixel areas PA may be surrounded by a boundary area BA. That is, FIG. 9B illustrates an embodiment in which four pixels are disposed in one pixel area PA. Furthermore, unlike in FIG. 4, pixels in the i^{th} row of pixels PLXᵢ and the (i−1)^{th} row of pixels PLXᵢ₋₁ may constitute one pixel area PA.

As described above, the display panel may include the organic layer that fills the opening having different depths, thereby improving manufacturing efficiency and a degree of integration.

While the invention has been described with reference to embodiments thereof, it will be apparent to those of ordinary skill in the art that various changes and modifications may be made thereto without departing from the spirit and scope of the invention as set forth in the following claims.

Accordingly, the scope of the invention should not be limited or determined by the described embodiments, and should be determined by the accompanying claims and the equivalents thereof

What is claimed is:

1. A display panel comprising:
a base layer including a boundary area and a pixel area;
a pixel circuit overlapping the pixel area;
a plurality of insulating layers which include at least a first insulating layer and in which an opening overlapping the boundary area is defined;
a first signal line disposed on the first insulating layer and overlapping the boundary area and the pixel area;
an organic layer including a first portion filling the opening; and
a light-emitting element disposed on the plurality of insulating layers and electrically connected to the pixel circuit,
wherein the opening includes:
a first area overlapping the first signal line, the first area having a first depth; and
a second area having a second depth greater than the first depth.

2. The display panel of claim 1, wherein the plurality of insulating layers further includes a second insulating layer disposed on the first insulating layer,
wherein the display panel further comprises a second signal line disposed on the second insulating layer and overlapping the boundary area and the pixel area, and
wherein the opening further includes a third area overlapping the second signal line, the third area having a third depth smaller than the first depth.

3. The display panel of claim 2, wherein the second area does not overlap the first signal line and the second signal line.

4. The display panel of claim 2, wherein the first signal line and the second signal line extend in a first direction, and
wherein the first area and the third area are spaced apart from each other with the second area therebetween in a second direction crossing the first direction.

5. The display panel of claim 2, wherein in the pixel area, the second insulating layer covers the first signal line.

6. The display panel of claim 2, wherein in the boundary area, a first surface of the organic layer facing the base layer contacts the first signal line and the second signal line.

7. The display panel of claim 1, further comprising:
a barrier layer disposed on the base layer,
wherein the opening exposes the barrier layer in the second area.

8. The display panel of claim 7, wherein in the second area, the barrier layer contacts the organic layer.

9. The display panel of claim 1, wherein the pixel circuit includes:
a first transistor including a first source area, a first drain area, a first channel area, and a first gate; and
a second transistor including a second source area, a second drain area, a second channel area disposed in a different layer from the first channel area, and a second gate disposed in a different layer from the first gate, and
wherein the first signal line is disposed in the same layer as the first gate or the second gate.

10. The display panel of claim 9, wherein the second transistor further includes a third gate electrically connected with the second gate and disposed in a different layer from the first gate and the second gate.

11. The display panel of claim 9, wherein the first transistor is a silicon transistor, and the second transistor is an oxide transistor.

12. The display panel of claim 1, wherein the boundary area includes a first boundary area extending in a first direction and a second boundary area extending in a second direction crossing the first direction, and
wherein the first signal line extends in the first direction.

13. The display panel of claim 1, wherein the plurality of insulating layers further includes a buffer layer disposed under the first insulating layer, a second insulating layer disposed on the first insulating layer, and a third insulating layer disposed on the second insulating layer,
wherein the first area penetrates the second insulating layer and the third insulating layer, and
wherein the second area penetrates the buffer layer and the first to third insulating layers.

14. The display panel of claim 1, wherein the first insulating layer includes a first insulating portion overlapping the boundary area,
wherein a first opening and a second opening are defined in the first insulating layer with the first insulating portion therebetween, and
wherein the first opening and the second opening constitute a portion of the opening of the plurality of insulating layers.

15. The display panel of claim 14, wherein the plurality of insulating layers further includes a second insulating layer disposed on the first insulating layer,
wherein the second insulating layer includes a second insulating portion overlapping the boundary area,
wherein a third opening and a fourth opening are defined in the second insulating layer with the second insulating portion therebetween, and
wherein the third opening and the fourth opening constitute a portion of the opening of the plurality of insulating layers.

16. The display panel of claim 1, further comprising:
an organic insulating layer disposed on the first portion and an outermost insulating layer farthest from the base layer among the plurality of insulating layers and contacting the first portion and the outermost insulating layer; and
a data line disposed on the organic insulating layer.

17. The display panel of claim 16, wherein the data line is connected to the pixel circuit through a contact hole defined through the organic layer.

18. The display panel of claim 1, wherein the organic layer further includes a second portion extending from the first portion and overlap the boundary area and the pixel area.

19. The display panel of claim 18, further comprising:
a data line disposed on the second portion,
wherein the data line is connected to the pixel circuit through a contact hole defined through the second portion.

20. The display panel of claim 1, wherein the pixel area includes a plurality of pixel areas,
wherein the boundary area surrounds each of the plurality of pixel areas in a plan view, and
wherein one light-emitting element, two light-emitting elements, or four light-emitting elements are disposed in each of the pixel areas.
